(19) United States
(12) Patent Application Publication
(10) Pub. No.: US 2026/0004829 A1
(43) Pub. Date: Jan. 1, 2026

(54) MEMORY CIRCUIT WITH BIT LINE CLAMPS

(71) Applicant: Xilinx, Inc., San Jose, CA (US)

(72) Inventors: Kumar Rahul, Hyderabad (IN); Santosh Yachareni, Hyderabad (IN); Md Hussain, Hyderabad (IN); Tabrez Alam, Hyderabad (IN); Nui Chong, San Jose, CA (US)

(21) Appl. No.: 18/758,730

(22) Filed: Jun. 28, 2024

(51) Int. Cl. G11C 7/12; G11C 7/06; G11C 7/10

(52) U.S. Cl. CPC G11C 7/12; G11C 7/06; G11C 7/1069; G11C 7/1075; G11C 7/1096

(57) ABSTRACT

A memory circuit is disclosed. The memory circuit includes a plurality of bit lines; a plurality of memory cells arranged in columns, each memory cell connected to a pair of bit lines; and a plurality of clamp circuits, each including a first clamp and logic circuit connected to a first bit line and a second clamp and logic circuit connected to a second bit line, where the first clamp and logic circuit is configured to selectively clamp the first bit line in response to the memory circuit operating in a particular mode, and where the second clamp and logic circuit is configured to selectively clamp the second bit line in response to the memory circuit operating in the particular mode.

### BACKGROUND

Memory circuits drive bit lines with pre-charge circuits and bit line drivers to write data to memory cells. In addition, the memory cells drive the bit lines to transmit the data stored therein during read operations. Some memory architectures use clamp circuits to prevent the voltages of bit lines from transitioning more than is necessary for sensing circuits to detect the stored data during read operations.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a memory circuit having clamp circuits according to some implementations.

FIG. 2 illustrates a clamp circuit according to some implementations.

FIG. 3 illustrates a clamping configuration according to some implementations.

FIG. 4 illustrates a truth table of a clamp circuit according to some implementations.

FIG. 5 illustrates a hardware implementation of the truth table of FIG. 4 according to some implementations.

FIG. 6 illustrates a hardware implementation of the truth table of FIG. 4 according to some implementations.

FIG. 7 illustrates a memory circuit having clamp circuits according to some implementations.

FIG. 8 illustrates a method of using a memory circuit according to some implementations.

FIG. 9 illustrates a method of using a memory circuit according to some implementations.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations, and should not be construed in a limited scope.

Reference to “an implementation,” “one implementation,” “an implementation,” or “one implementation” in the framework of the present description is intended to indicate that a particular configuration, structure, or characteristic described in relation to the implementation/implementation is included in at least one implementation/implementation. Hence, phrases such as “in one implementation” or “in one implementation” that may be present in one or more points of the present description do not necessarily refer to one and the same implementation/implementation. Moreover, particular conformations, structures, or characteristics may be combined in any adequate way in one or more implementations/implementations. The references used herein are provided merely for convenience and hence do not define the extent of protection or the scope of the implementations/implementations.

The present disclosure relates to memory circuits, particularly to techniques for reducing power consumption and improving reliability in True Dual Port (TDP) memory circuits. As the technology scales, some clamp circuits with unselected columns experience more significant reliability issues. Specifically, in advanced technology nodes such as 3 nm and beyond, reliability issues such as electromigration (EM) violations have become more prevalent. For example, during a read operation, some clamp circuits in columns which are not selected for the read operation experience a DC current path from the clamp circuit to portions of bitcells of the column which are storing low values. As a result, the current from the clamp circuit to the bitcells cause electromigration (EM) violations in the conductors between the clamp circuits and the bitcells. The problem also results in unnecessary increased power consumption. The present disclosure provides solutions to these challenges by introducing circuit architectures and methods that enhance the performance and reliability of memory circuits in various operational modes.

In some implementations, the disclosed memory circuit includes a plurality of bit lines and memory cells arranged in columns, with each memory cell connected to a pair of bit lines for each memory access port. Each column of the memory circuit further comprises a clamp circuit, having a clamp and logic circuit connected to each of the bit lines of the column. These clamp circuits are configured to selectively clamp the bit lines in response to the memory circuit operating in a particular mode, such as a read first mode. The selective clamping is designed to address the reliability issues associated with continuous DC paths in unselected columns, which can lead to EM violations and increased power consumption.

In implementations discussed herein, clamp circuits in unselected columns during read first operations, selected & unselected columns in other modes (mentioned in later point) are disabled. This prevents the DC current path from the clamp circuits in unselected columns to the bitcells resulting in improved reliability and reduced power consumption. For example, in a read first mode, the disclosed architecture can achieve power savings of approximately 22% at the Block Random Access Memory (BRAM) array level, and an additional power savings of approximately 15% in write first and no change modes.

In some implementations, during read first operational modes, the clamp circuits in unselected columns during read operations are disabled. In some implementations, during write first modes, the clamp circuits of all columns are disabled. In some implementations, during No change modes, the clamp circuits of all columns are disabled.

In some implementations, the circuits are implemented in pre-existing designs with no area impact.

The benefits of the disclosed memory circuit extend to the behavior of data output latches during write operation cycles. In various operational modes, such as write first, read first, and no change modes, the data output latches exhibit distinct behaviors that contribute to the overall efficiency and performance of the memory circuit. The disclosed techniques ensure that the data output latches operate in a manner that supports the desired mode of operation while minimizing power consumption and enhancing data integrity.

Overall, the disclosed memory circuit and methods provide a solution to the challenges faced in advanced semiconductor technology nodes. By selectively enabling and disabling clamp circuits based on the operational mode, the disclosed techniques improve the reliability and power efficiency of TDP memory circuits.

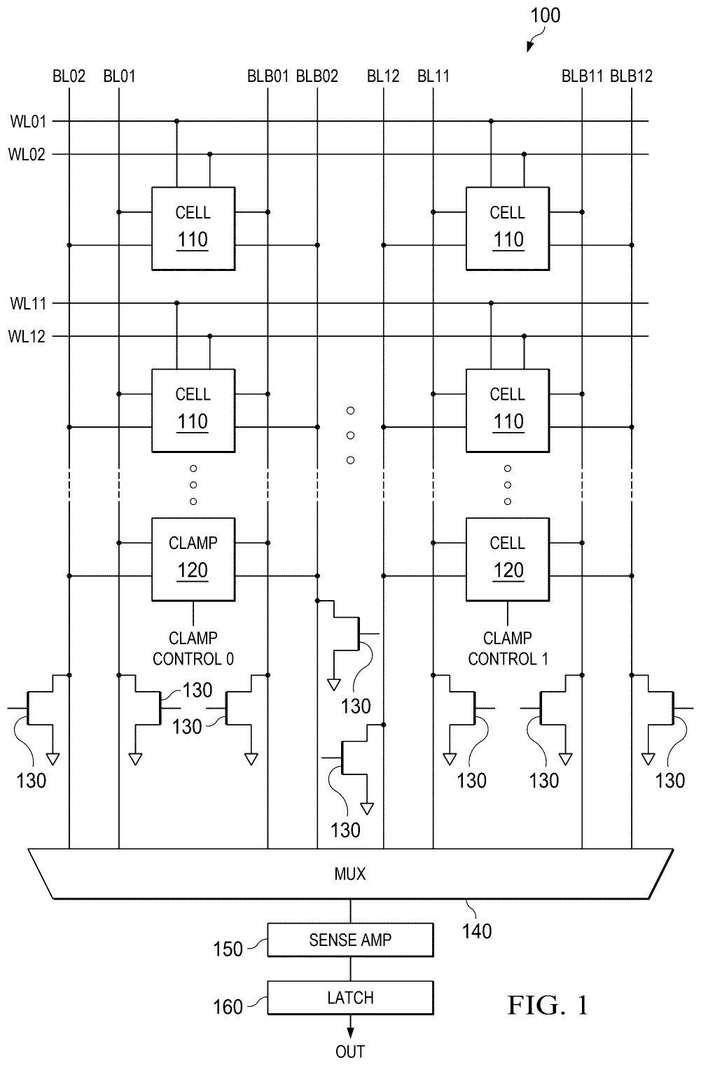

FIG. 1 illustrates a dual port memory circuit 100 having clamp circuits according to some implementations. Memory circuit 100 includes memory cells 110, clamp circuits 120, write drivers 130, read multiplexer 140, sense amplifier 150, and latch 160. Memory circuit 100 illustrates an implementation sized for convenient illustration and description of relevant aspects. Other implementations are, for example, much larger.

A particular target memory cell of memory cells 110 may be written in a write operation of either port during which the particular row of memory cells 110 having the target memory cell is activated using word line signals on word line WL01, WL02, WL11, or WL12 generated, for example, by word line drivers (not shown). In addition, the data to be written to the target memory cell is driven to bit lines BL01 and BLB01, BL02 and BLB02, BL11 and BLB11, or BL12 and BLB12 using write drivers 130. As a result, the data driven to the bit lines of the column of memory cells 110 having the target memory cell is received by the target memory cell because the word line signals on the word line of the row of memory cells 110 having the target memory cell cause the target memory cell to be active.

To read a particular target memory cell of memory cells 110 during a read operation, the particular row of memory cells 110 having the target memory cell is activated using word line signals on word line WL01, WL02, WL11, or WL12 generated, for example, by word line drivers (not shown). In addition, multiplexer 140 receives selection signals identifying the column of memory cells 110 having the target memory cell. Furthermore, the multiplexer electrically connects the bit lines BL01 and BLB01, BL02 and BLB02, BL11 and BLB11, or BL12 and BLB12 of the column of memory cells 110 having the target memory cell to sense amplifier 150. During the read operation, the write drivers 130 are inactive. As a result, the data stored in the target memory cell is driven by the target memory cell to the bit lines BL01 and BLB01, BL02 and BLB02, BL11 and BLB11, or BL12 and BLB12 of the column of memory cells 110 having the target memory cell. Furthermore, the sense amplifier 150, being electrically connected with the bit lines of the column of memory cells 110 having the target memory cell by multiplexer 140, amplifies the difference between the signals it receives to generate a digital output bit corresponding with the data stored in the target memory cell.

Latch 160 is configured to receive the digital output bit from sense amplifier 150, and to store the digital output bit and to conditionally transmit the digital output bit to other circuitry.

At least to increase speed and to reduce power of the memory circuit 100, during read operations, clamp circuits 120 clamp the bit lines to limit the signal deviation of the bit lines from their initial values. The limited deviation reduces the time necessary, after the read operation, to restore the bit lines to their initial values.

Some implementations have multiple modes of operating.

For example, some implementations operate using a write first mode. In the write first mode, data is written into a target memory cell using a first port, the target memory cell is also read, for example, using the same first port. Accordingly, the data being written to the target memory cell is simultaneously provided to sense amplifier 150. As a result, data stored in the data output is transparent to the write data, bypassing the memory, and the data bit generated by sense amplifier 150 follows the input data being written. Accordingly, any port operating in the write of the write first mode will write new data into a memory cell and read the new data by bypassing the memory cell.

In some implementations, clamp circuits 120 are disabled during the write first mode. As a result, the bit lines are permitted to deviate from their initial state without limitation from the clamp circuits 120, which contributes to power savings and stability of the data. In some implementations, clamp circuits 120 are not disabled during the write first mode.

Some implementations operate using a read first mode. In the read first mode, data previously stored at a target memory cell is provided to the sense amplifier 150 with a first port and latched with latch 160, for example, as discussed above. In addition, during the same memory clock cycle, once the data being read is latched, new data is written to the target memory cell, for example, with the same first port, for example, as discussed above. Accordingly, any port operating in the write of the read first mode will read old data from a memory cell and subsequently write new data to the memory cell.

In some implementations, clamp circuits 120 are selectively enabled during the read first mode, as discussed in more detail below. As a result, the bit lines deviation from their initial state is limited by clamp circuits 120, which also contributes to better performance and improved speed. In some implementations, clamp circuits 120 are disabled during the read first mode, such that the bit lines are permitted to deviate from their initial state without limitation from the clamp circuits 120. In some implementations, certain clamp circuits 120 are always disabled during the read first mode.

Some implementations operate in a no change mode. In the no change mode, the output of latch 160 for a first port remains unchanged during a write operation. Accordingly, the data output for the first port remains equal to the last read data and is unaffected by the write operation. Therefore, any port operating in the write of the no change mode will write new data to the memory cell. In some implementations, clamp circuits 120 are disabled during the no change mode, which prevents unnecessary clamping of the bit lines and contributes to power savings. This selective operation of clamp circuits in various modes, including the no change mode, ensures that power consumption is optimized.

Some implementations operate in a read only mode. In the read only mode, the output of latch 160 for a first port corresponds with the data stored in the memory cell being read. Accordingly, any port operating in the read only mode will read the most previously written data from the memory cell. In some implementations, clamp circuits 120 are disabled during the read only mode, which prevents unnecessary clamping of the bit lines and contributes to power savings. This selective operation of clamp circuits in various modes, including the read only mode, ensures that power consumption is optimized.

Some implementations selectively operate in any one of the write first mode, the read first mode, and the no change mode. Some implementations selectively operate in any two of the write first mode, the read first mode, and the no change mode. Some implementations selectively operate in any of the write first mode, the read first mode, and the no change mode. Some implementations operate in one or more different modes.

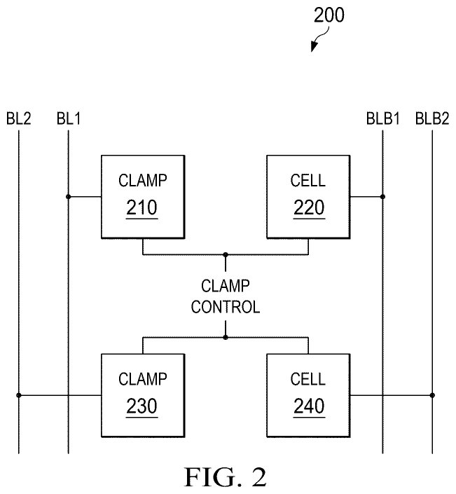

FIG. 2 illustrates a clamp circuit 200 according to some implementations. Clamp circuit 200 may be used, for example, in clamp circuit 120 of memory circuit 100. Alternative implementations of memory circuit 100 use alternative clamp circuits having features similar or identical to clamp circuit 200. Clamp circuit 200 includes clamp and logic circuits 210, 220, 230, and 240.

Clamp and logic circuit 210 is configured to receive clamp control signals and to selectively clamp bit line BL1 according to the clamp control signals it receives. Clamp and logic circuit 220 is configured to receive clamp control signals and to selectively clamp bit line BLB1 according to the clamp control signals it receives. Clamp and logic circuit 230 is configured to receive clamp control signals and to selectively clamp bit line BL2 according to the clamp control signals it receives. Clamp and logic circuit 240 is configured to receive clamp control signals and to selectively clamp bit line BLB2 according to the clamp control signals it receives.

The clamp control signals indicate various memory circuit conditions during read and write operations of the various operational modes.

In some implementations the clamp control signals include a mode signal indicating which operational mode the memory circuit is operating in. In some implementations, each clamp and logic circuit receives a separate mode signal. In some implementations, both clamp and logic circuits of a single port receive the same mode signal. In some implementations, clamp and logic circuits of a first port receive a different mode signal as that mode signal received by the clamp and logic circuits of a second port. In some implementations, clamp and logic circuits of a first port receive the same mode signal as that mode signal received by the clamp and logic circuits of a second port.

In some implementations, the clamp control signals include a write first signal indicating whether the memory circuit is operating in a write first mode. In some implementations, each clamp and logic circuit receive a separate write first signal. In some implementations, both clamp and logic circuits of a single port receive the same write first signal. In some implementations, clamp and logic circuits of a first port receive a different write first signal as that write first signal received by the clamp and logic circuits of a second port. In some implementations, clamp and logic circuits of a first port receive the same write first signal as that write first signal received by the clamp and logic circuits of a second port.

In some implementations, the clamp control signals include a read first signal indicating whether the memory circuit is operating in a read first mode. In some implementations, each clamp and logic circuit receives a separate read first signal. In some implementations, both clamp and logic circuits of a single port receive the same read first signal. In some implementations, clamp and logic circuits of a first port receive a different read first signal as that read first signal received by the clamp and logic circuits of a second port. In some implementations, clamp and logic circuits of a first port receive the same read first signal as that read first signal received by the clamp and logic circuits of a second port.

In some implementations, the clamp control signals include a no change signal indicating whether the memory circuit is operating in a no change mode. In some implementations, each clamp and logic circuit receives a separate no change signal. In some implementations, both clamp and logic circuits of a single port receive the same no change signal. In some implementations, clamp and logic circuits of a first port receive a different no change signal as that no change signal received by the clamp and logic circuits of a second port. In some implementations, clamp and logic circuits of a first port receive the same no change signal as that no change signal received by the clamp and logic circuits of a second port.

In some implementations, the clamp control signals include a column select signal indicating whether the column of memory cells connected to bit lines BL1, BLB1, BL2, and BLB2 is selected during a read or a write operation. In some implementations, each clamp and logic circuit receives a separate column select signal. In some implementations, both clamp and logic circuits of a single port receive the same column select signal. In some implementations, clamp and logic circuits of a first port receive a different column select signal as that column select signal received by the clamp and logic circuits of a second port. In some implementations, clamp and logic circuits of a first port receive the same column select signal as that column select signal received by the clamp and logic circuits of a second port.

In some implementations, the clamp control signals include a write signal indicating whether the column of memory cells connected to bit lines BL1, BLB1, BL2, and BLB2 are being used for a write operation. In some implementations, each clamp and logic circuit receives a separate write signal. In some implementations, both clamp and logic circuits of a single port receive the same write signal. In some implementations, clamp and logic circuits of a first port receive a different write signal as that write signal received by the clamp and logic circuits of a second port. In some implementations, clamp and logic circuits of a first port receive the same write signal as that write signal received by the clamp and logic circuits of a second port.

In some implementations, the clamp control signals include a read signal indicating whether the column of memory cells connected to bit lines BL1, BLB1, BL2, and BLB2 are being used for a read operation. In some implementations, each clamp and logic circuit receives a separate read signal. In some implementations, both clamp and logic circuits of a single port receive the same read signal. In some implementations, clamp and logic circuits of a first port receive a different read signal as that read signal received by the clamp and logic circuits of a second port. In some implementations, clamp and logic circuits of a first port receive the same read signal as that read signal received by the clamp and logic circuits of a second port.

Accordingly, in some implementations, each of the control signals may be used for clamping and not clamping a single bit line, such that clamping and not clamping the bit lines of one or more or all ports are individually conditioned by the state of each control signal. Furthermore, in some implementations, each of the control signals may be used for clamping and not clamping a pair of bit lines of the same port, such that clamping and not clamping the pairs of bit lines of one or more or all ports are conditioned by the state of each control signal. In addition, in some implementations, each of the control signals may be used for clamping and not clamping pairs of bit lines of the multiple ports, such that clamping and not clamping the pairs of bit lines of two or more or all ports are conditioned by the state of each control signal.

The following discussion relates to enabling and disabling clamping circuits according to certain specific control signal conditions. Other implementations may use different control signals and control signal conditions to enable and disable clamping circuits.

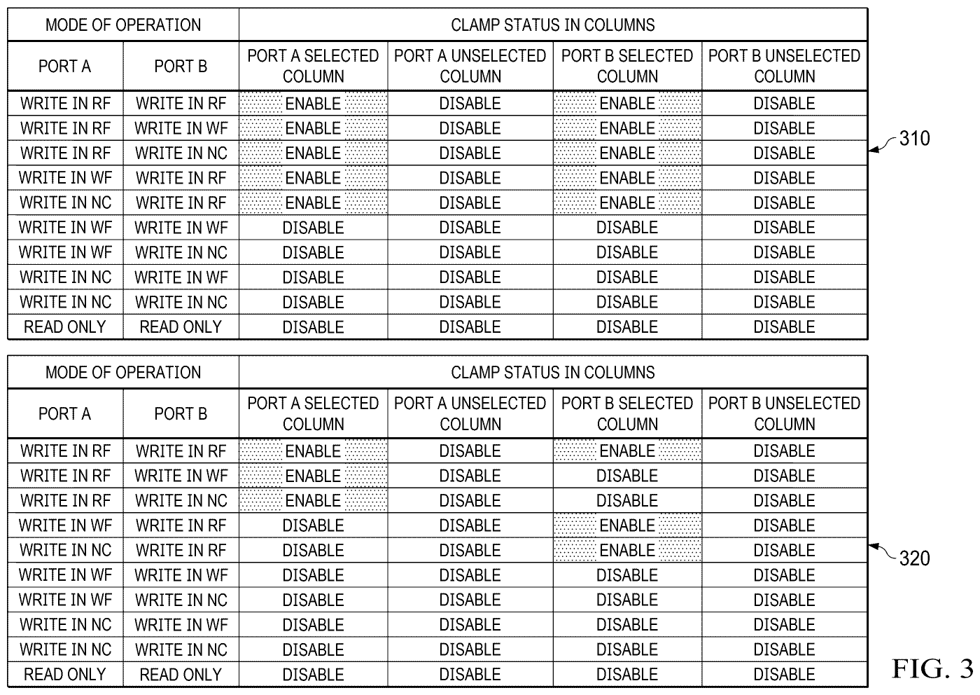

FIG. 3 illustrates clamping configurations 310 and 320 for a dual port memory having port A and port B according to some implementations.

Clamping configuration 310 may be used when port A and port B share a common read first signal indicating that either of the ports is in a read first operational mode.

When a memory operates according to clamping configuration 310, if either port A or port B is in a read first mode (as indicated by the read first signal), clamps of columns which are selected are enabled, where the selected columns are indicated by the state of certain control signals. In addition, if either port A or port B is in a read first mode, clamps of columns which are unselected are disabled, where the unselected columns are indicated by the state of the certain control signals.

In addition, when the memory operates according to clamping configuration 310, if both port A and port B is in another operational mode, and neither port A nor port B is in the read first mode (as indicated by the read first signal), clamps of all columns are disabled.

Clamping configuration 320 may be used when port A and port B have separate read first signals respectively indicating that port A or port B is in the read first operational mode.

When a memory operates according to clamping configuration 320, if port A is in the read first mode (as indicated by the read first signal of port A), clamps of columns of port A which are selected are enabled, where the selected columns are indicated by the state of certain control signals. In addition, if port A is in the read first mode, clamps of columns of port A which are unselected are disabled, where the unselected columns are indicated by the state of the certain control signals.

In addition, when the memory operates according to clamping configuration 320, if port A is not in the read first mode (as indicated by the read first signal of port A), clamps of all columns of port A are disabled. Accordingly, whether the clamps of the columns of port A are enabled or disabled is independent of the operational mode of port B.

Furthermore, when a memory operates according to clamping configuration 320, if port B is in the read first mode (as indicated by the read first signal of port B), clamps of columns of port B which are selected are enabled, where the selected columns are indicated by the state of certain control signals. In addition, if port B is in the read first mode, clamps of columns of port B which are unselected are disabled, where the unselected columns are indicated by the state of the certain control signals.

In addition, when the memory operates according to clamping configuration 320, if port B is not in the read first mode (as indicated by the read first signal of port B), clamps of all columns of port B are disabled. Accordingly, whether the clamps of the columns of port B are enabled or disabled is independent of the operational mode of port A.

In addition, when the memory operates according to clamping configuration 320, if port B is not in the read first mode (as indicated by the read first signal of port B), clamps of all columns of port B are disabled. Accordingly, whether the clamps of the columns of port B are enabled or disabled is independent of the operational mode of port A.

The following discussion relates to enabling and disabling clamping circuits according to certain specific control signal conditions. Other implementations may use different control signals and control signal conditions to enable and disable clamping circuits. The discussed implementations may be used to implement either of clamping configurations 310 and 320, and may be used to implement other clamping configurations not specifically discussed.

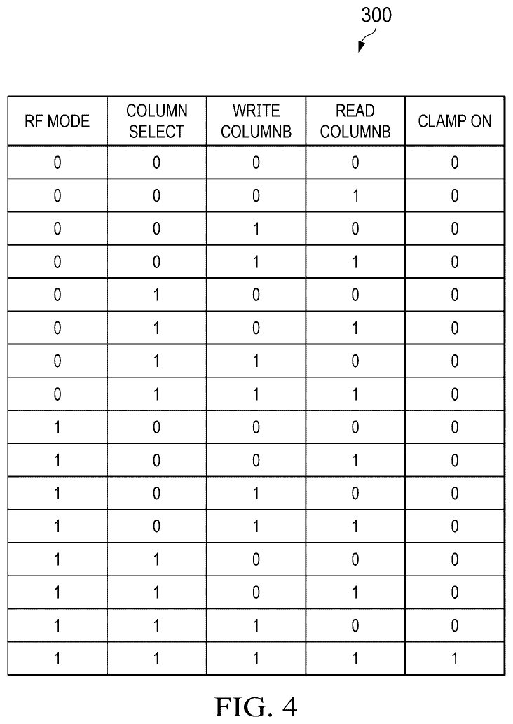

FIG. 4 illustrates a truth table 300 of a clamp and logic circuit according to some implementations. For example, clamp and logic circuits 210 and 220 may be configured to selectively clamp bit lines BL1, BLB1, BL2, and BLB2 according to the logic of truth table 300.

In the illustrated implementation, the inputs of truth table 300 include RF Mode, Column Select, Write ColumnB, and Read Column.

The RF Mode input provides an indication as to whether the memory circuit is operating in a read first mode. In the truth table, the RF Mode input having a value of 1 indicates that the memory circuit is operating in the read first mode, and the RF Mode input having a value of 0 indicates that the memory circuit is not operating in the read first mode.

The Column Select input provides an indication as to whether the column of memory cells connected to the bit line of the clamp and logic circuit is selected during a read or a write operation. In the truth table 300, the Column Select input having a value of 1 indicates that the column of memory cells connected to the bit line of the clamp and logic circuit is selected during a read or a write operation, and the Column Select input having a value of 0 indicates that the column of memory cells connected to the bit line of the clamp and logic circuit is not selected during a read or a write operation.

The Write ColumnB input provides an indication as to whether the bit line connected to the clamp and logic circuit is being used for a write operation. In the truth table 300, the Write ColumnB input having a value of 1 indicates that the bit line connected to the clamp and logic circuit is not being used for a write operation, and the Write ColumnB input having a value of 0 indicates that the bit line connected to the clamp and logic circuit is being used for a write operation.

The Read ColumnB input provides an indication as to whether the column of memory cells connected to the bit line of the clamp and logic circuit is being used for a read operation. In the truth table 300, the Read ColumnB input having a value of 1 indicates that the column of memory cells connected to the bit line of the clamp and logic circuit is not being used for a read operation, and the Read ColumnB input having a value of 0 indicates that the column of memory cells connected to the bit line of the clamp and logic circuit is being used for a read operation.

Truth table 300 indicates that the clamp is enabled if the memory circuit is operating in the read first mode, the column of memory cells connected to the bit line of the clamp and logic circuit is selected, the bit lines connected to the clamp and logic circuit are clamped once read operation finishes in read first mode and depending on data being written one of the bit line clamp gets disabled. Truth table 300 indicates that the clamp is disabled if any of: the memory circuit is not operating in the read first mode, the column of memory cells connected to the bit line of the clamp and logic circuit is not selected during a read or a write operation, the bit line connected to the clamp and logic circuit is being used for a write operation, and the column of memory cells connected to the bit line of the clamp and logic circuit is being used for a read operation.

In alternative implementations, the clamp and logic circuit may operate according to a different truth table. In alternative implementations, clamp and logic circuits operate according to different inputs.

For example, in some implementations, the truth table 300 includes an input related to a different mode. Accordingly, in some implementations the clamp is enabled if the memory circuit is operating in a particular mode different from the read first mode, and the clamp is disabled if the memory circuit is not operating in the particular mode. In some implementations, the clamp is enabled if the memory circuit is operating in a particular combination of specified modes, and the clamp is disabled if the memory circuit is not operating in the particular combination of specified modes.

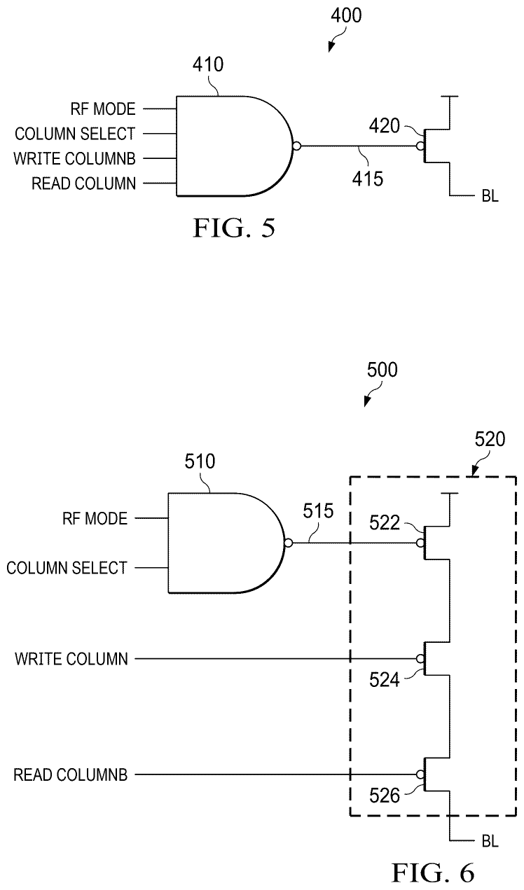

FIG. 5 illustrates a hardware schematic implementation of a clamp and logic circuit 400 of the truth table of FIG. 4 according to some implementations.

Clamp and logic circuit 400 includes NAND gate 410 and clamp 420.

NAND gate 410 receives a RF Mode input, a Column Select input, a Write ColumnB input, and a Read Column input. In addition, NAND gate 410 generates a high value at node 415 if the RF Mode input, the Column Select input, the Write ColumnB input, and the Read Column input indicate that any of: the column of memory cells connected to the bit line of the clamp and logic circuit is not selected during write operation in read first mode. As a result, the clamp will be disabled if the memory is not working in write in read first mode. If memory is in a write portion of the read first mode then clamps of unselected columns will remain disabled.

In response to the high value at node 415, clamp 420 is off, and does not clamp bit line BL.

In addition, NAND gate 410 generates a low value at node 415 if all of:
the RF Mode input indicates that the memory circuit is operating in the read first mode,
the Column Select input indicates that the column of memory cells connected to the bit line of the clamp and logic circuit is selected during a read or a write operation,
the Write ColumnB input indicates that the bit line connected to the clamp and logic circuit is not being used for a write operation, and
the Read Column input indicates that the column of memory cells connected to the bit line of the clamp and logic circuit is not being used for a read operation.

In response to the low value at node 415, clamp 420 is on and it clamps bit line BL. As a result, a target memory cell sinking current from the bit line BL is opposed by clamp 420 sourcing current to the bit line BL. Consequently, the voltage of bit line BL is not pulled all the way to ground by the target memory cell. Instead, the voltage of bit line BL is reduced from its initial voltage to a voltage corresponding with the difference between the current sunk by the target memory cell and the current sourced by clamp 420. In some implementations, the sizes of the target memory cell devices sinking the current and the size of clamp 420 are designed so that the voltage of bit line BL is pulled down by target memory cell to a voltage sufficient to allow a sense amplifier, such as sense amplifier 150 of FIG. 1 to reliably generate an output corresponding with the data of the target memory cell.

FIG. 6 illustrates a hardware schematic implementation of a clamp and logic circuit 500 of the truth table of FIG. 4 according to some implementations.

Clamp and logic circuit 500 includes NAND gate 510 and clamp 520.

NAND gate 510 receives a RF Mode input and a Column Select input. In addition, NAND gate 510 generates a high value at node 515 if the RF Mode input and the Column Select input indicate that either of: the memory circuit is not operating in the read first mode, and the column of memory cells connected to the bit line of the clamp and logic circuit is not selected during a read or a write operation.

In response to the high value at node 515, transistor 522 of clamp 520 is off, and clamp 520 does not clamp Bit line BL. Accordingly, if the memory is in a read first mode in RF mode then 522 will be off during read operation and once read operation done it can turn on.

Transistor 524 of clamp 520 receives a Write Column input. In addition, if the Write Column input indicates that the bit line connected to the clamp and logic circuit is being used for a write operation, transistor 524 is off, and clamp 520 does not clamp bit line BL.

Transistor 526 of clamp 520 receives a Read ColumnB input. In addition, if the Read ColumnB input indicates that the column of memory cells connected to the bit line of the clamp and logic circuit is being used for a read operation, transistor 526 is off, and clamp 520 does not clamp bit line BL.

In addition, NAND gate 510 generates a low value at node 515 if:
the RF Mode input indicates that the memory circuit is operating in the read first mode, and
the Column Select input indicates that the column of memory cells connected to the bit line of the clamp and logic circuit is selected during write operation in read first mode.

In response to the low value at node 515, transistor 522 of clamp 520 is on and clamp 520 clamps bit line BL if transistors 524 and 526 are also on.

If the Write Column input indicates that the bit line connected to the clamp and logic circuit is not being used for a write operation, transistor 524 is on, and clamp 520 clamps bit line BL if transistors 522 and 526 are also on.

If the Read ColumnB input indicates that the column of memory cells connected to the bit line of the clamp and logic circuit is not being used for a read operation, transistor 526 is on, and clamp 520 clamps bit line BL if transistors 522 and 524 are also on.

As a result of clamp 520 clamping bit line BL, a target memory cell sinking current from the bit line BL is opposed by clamp 520 sourcing current to the bit line BL. Consequently, the voltage of bit line BL is not pulled all the way to ground by the target memory cell. Instead, the voltage of bit line BL is reduced from its initial voltage to a voltage corresponding with the difference between the current sunk by the target memory cell and the current sourced by clamp 520. In some implementations, the sizes of the target memory cell devices sinking the current and the size of clamp 520 are designed so that the voltage of bit line BL is pulled down by target memory cell to a voltage sufficient to allow a sense amplifier, such as sense amplifier 150 of FIG. 1 to reliably generate an output corresponding with the data of the target memory cell.

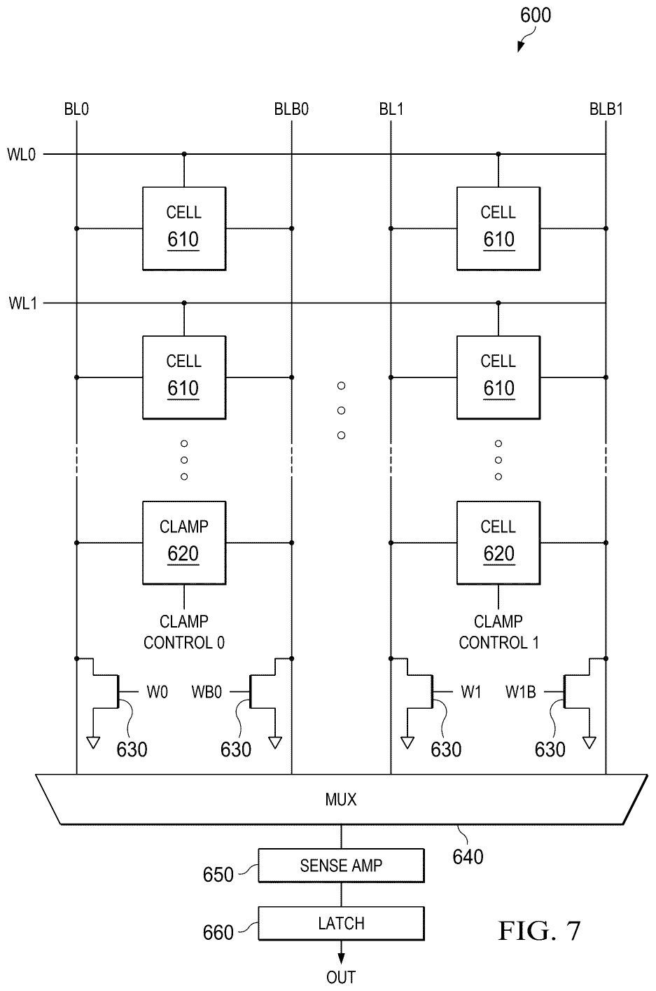

FIG. 7 illustrates a single port memory circuit 600 having clamp circuits according to some implementations. Memory circuit 600 includes memory cells 610, clamp circuits 620, write devices 630, read multiplexer 640, sense amplifier 650, and latch 660. Memory circuit 600 illustrates an implementation sized for convenient illustration and description of relevant aspects. Other implementations are, for example, much larger.

A particular target memory cell of memory cells 610 may be written in a write operation during which the particular row of memory cells 610 having the target memory cell is activated using word line signals WL0 or WL1 generated, for example, by word line drivers (not shown). In addition, the data to be written to the target memory cell is driven to bit lines BL0 and BLB0, BL1 and BLB1 using write devices 630. As a result, the data driven to the bit lines of the column of memory cells 610 having the target memory cell is received by the target memory cell because the word line signals on the word line of the row of memory cells 610 having the target memory cell cause the target memory cell to be active.

A particular target memory cell of memory cells 610 may be read in a read operation during which the particular row of memory cells 610 having the target memory cell is activated using bit line signals on bit line BL0 or BL1 generated, for example, by bit line drivers (not shown). In addition, multiplexer 640 receives selection signals identifying the column of memory cells 610 having the target memory cell. Furthermore, the multiplexer electrically connects the bit lines BL0 and BLB0, or BL1 and BLB1 of the column of memory cells 610 having the target memory cell to sense amplifier 650. During the read operation, the write devices 630 are inactive. As a result, the data stored in the target memory cell is driven by the target memory cell to the bit lines BL0 and BLB0, or BL1 and BLB1 of the column of memory cells 610 having the target memory cell. Furthermore, the sense amplifier 650, being electrically connected with the bit lines of the column of memory cells 610 having the target memory cell by multiplexer 640, amplifies the difference between the signals it receives to generate a digital output bit corresponding with the data stored in the target memory cell.

Latch 660 is configured to receive the digital output bit from sense amplifier 650, and to store the digital output bit and to conditionally transmit the digital output bit to other circuitry.

At least to increase speed of the memory circuit 600, during read operations, clamp circuits 620 clamp the bit lines to limit the signal deviation of the bit lines from their initial values. The limited deviation reduces the time necessary, after the read operation, to restore the bit lines to their initial values.

Some implementations have multiple modes of operating.

For example, some implementations operate using a write first mode. In the write first mode, input while data is written into a target memory cell, the target memory cell is also read. Accordingly, the data being written to the target memory cell is simultaneously provided to sense amplifier 650. As a result, data stored in the data output is transparent to the write data, bypassing the memory, and the data bit generated by sense amplifier 650 follows the input data being written.

In some implementations, clamp circuits 620 are disabled during the write first mode. As a result, the bit lines are permitted to deviate from their initial state without limitation from the clamp circuits 620. In some implementations, clamp circuits 620 are not disabled during the write first mode.

Some implementations operate using a read first mode. In the read first mode, data previously stored at a target memory cell is provided to the sense amplifier 650 and latched with latch 660, for example, as discussed above. In addition, during the same memory clock cycle, once the data being read is latched, new data is written to the target memory cell, for example, as discussed above.

In some implementations, clamp circuits 620 are selectively enabled during the read first mode, as discussed in more detail with reference to clamp circuits discussed above. As a result, the bit lines deviation from their initial state is limited by clamp circuits 620. In some implementations, clamp circuits 620 are disabled during the read first mode, such that the bit lines are permitted to deviate from their initial state without limitation from the clamp circuits 620.

Some implementations operate in a no change mode. In the no change mode, the output of latch 660 remains unchanged during a write operation. Accordingly, the data output remains equal to the last read data and is unaffected by the write operation.

Some implementations selectively operate in any one of the write first mode, the read first mode, and the no change mode. Some implementations selectively operate in any two of the write first mode, the read first mode, and the no change mode. Some implementations selectively operate in any of the write first mode, the read first mode, and the no change mode. Some implementations operate in one or more different modes.

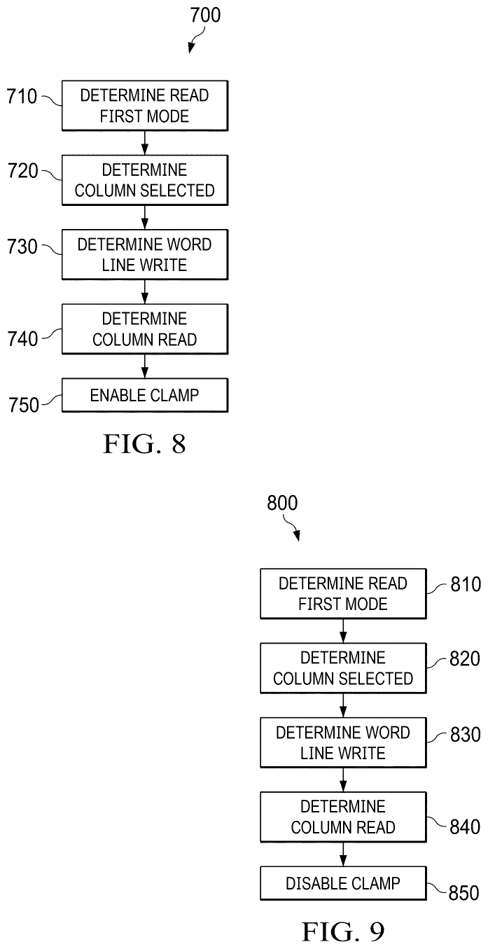

FIG. 8 illustrates a method 700 of using a memory circuit according to some implementations. Method 700 may be performed, for example, by a memory circuit such as memory circuit 100 or memory circuit 600. In some implementations, memory circuit 100, memory circuit 600, or another memory circuit perform methods having similar or identical aspects to those of method 700.

At block 710, the memory circuit receives one or more mode signals indicating whether the memory circuit is operating in a read first mode. For example, the memory circuit may selectively operate in one or more modes including, but not limited to, a write first mode, a read first mode, and a no change mode, and the memory circuit may receive an indication regarding which operating mode the memory circuit is to operate in. In addition, the memory circuit may provide an indication to each clamp and logic circuit of the memory circuit indicating whether the memory circuit is operating in a read first mode, for example, with an RF Mode input.

At block 720, the memory circuit provides one or more mode signals to each clamp and logic circuit of the memory circuit indicating whether the column of memory cells connected to the bit line of the clamp and logic circuit is selected for a read or a write operation. For example, the memory circuit may generate a Column Select input to indicate to each clamp and logic circuit whether the column of memory cells connected to the bit line of the clamp and logic circuit is selected for a read or a write operation.

At block 730, the memory circuit provides one or more mode signals to each clamp and logic circuit of the memory circuit indicating whether the bit line connected to the clamp and logic circuit is selected for a write operation. For example, the memory circuit may generate a Write ColumnB input to indicate to each clamp and logic circuit whether the bit line connected to the clamp and logic circuit is selected for a write operation.

At block 740, the memory circuit provides one or more mode signals to each clamp and logic circuit of the memory circuit indicating whether the column of memory cells connected to the bit line of the clamp and logic circuit is selected for a read operation. For example, the memory circuit may generate a Read Column input to indicate to each clamp and logic circuit whether the column of memory cells connected to the bit line of the clamp and logic circuit is selected for a read operation.

At block 750, each clamp and logic circuit is enabled and clamps the bit line connected thereto if:
the memory circuit is operating in the read first mode,
the column of memory cells connected to the bit line of the clamp and logic circuit is selected for a read or a write operation,
the bit line connected to the clamp and logic circuit is not being used for a write operation, and
the column of memory cells connected to the bit line of the clamp and logic circuit is not currently being used for a read operation.

FIG. 9 illustrates a method 800 of using a memory circuit according to some implementations. Method 800 may be performed, for example, by a memory circuit such as memory circuit 100 or memory circuit 600. In some implementations, memory circuit 100, memory circuit 600, or another memory circuit perform methods having similar or identical aspects to those of method 800.

At block 810, the memory circuit receives one or more mode signals indicating whether the memory circuit is operating in a read first mode. For example, the memory circuit may selectively operate in one or more modes including, but not limited to, a write first mode, a read first mode, and a no change mode, and the memory circuit may receive an indication regarding which operating mode the memory circuit is to operate in. In addition, the memory circuit may provide an indication to each clamp and logic circuit of the memory circuit indicating whether the memory circuit is operating in a read first mode, for example, with an RF Mode input.

At block 820, the memory circuit provides one or more mode signals to each clamp and logic circuit of the memory circuit indicating whether the column of memory cells connected to the bit line of the clamp and logic circuit is selected for a read or a write operation. For example, the memory circuit may generate a Column Select input to indicate to each clamp and logic circuit whether the column of memory cells connected to the bit line of the clamp and logic circuit is selected for a read or a write operation.

At block 830, the memory circuit provides one or more mode signals to each clamp and logic circuit of the memory circuit indicating whether the bit line connected to the clamp and logic circuit is selected for a write operation. For example, the memory circuit may generate a Write ColumnB input to indicate to each clamp and logic circuit whether the bit line connected to the clamp and logic circuit is selected for a write operation.

At block 840, the memory circuit provides one or more mode signals to each clamp and logic circuit of the memory circuit indicating whether the column of memory cells connected to the bit line of the clamp and logic circuit is selected for a read operation. For example, the memory circuit may generate a Read Column input to indicate to each clamp and logic circuit whether the column of memory cells connected to the bit line of the clamp and logic circuit is selected for a read operation.

At block 850, each clamp and logic circuit is disabled and does not clamp the bit line connected thereto if any of:
the memory circuit is not operating in the read first mode,
the column of memory cells connected to the bit line of the clamp and logic circuit is not selected during a read or a write operation,
the bit line connected to the clamp and logic circuit is being used for a write operation, and
the column of memory cells connected to the bit line of the clamp and logic circuit is being used for a read operation.

One general aspect is a memory circuit, including a plurality of bit lines; a plurality of memory cells arranged in columns, each memory cell connected to a pair of bit lines; and a plurality of clamp circuits, each including a first clamp and logic circuit connected to a first bit line and a second clamp and logic circuit connected to a second bit line, where the first clamp and logic circuit is configured to selectively clamp the first bit line in response to the memory circuit operating in a particular mode, and where the second clamp and logic circuit is configured to selectively clamp the second bit line in response to the memory circuit operating in the particular mode.

Implementations may include one or more of the following features. The memory circuit, where the particular mode is a read first mode. The memory circuit, where the first and second clamp and logic circuits do not respectively clamp the first and second bit lines in response to the memory circuit operating in a write first mode or in a no change mode. The memory circuit, where the first and second clamp and logic circuits clamp the first and second bit lines if, in addition to the memory circuit operating in the particular mode, a column of memory cells connected to the first and second bit lines of the first and second clamp and logic circuits is selected for a read or a write operation. The memory circuit, where the first clamp and logic circuit clamps the first bit line if, in addition to the memory circuit operating in the particular mode, the first bit line is used for a write operation. The memory circuit, where the second clamp and logic circuit clamps the second bit line if, in addition to the memory circuit operating in the particular mode, the second bit line is used for a write operation. The memory circuit, where the first and second clamp and logic circuits clamp the first and second bit lines if, in addition to the memory circuit operating in the particular mode, a column of memory cells connected to the first and second bit lines is being used for a read operation. The memory circuit, where the memory circuit is a multiport memory.

One general aspect is a memory system, including a plurality of bit lines; a plurality of memory cells arranged in columns, each memory cell connected to first and second bit lines; a plurality of clamp circuits, each including a first clamp and logic circuit connected to a first bit line and a second clamp and logic circuit connected to a second bit line, where the first clamp and logic circuit is configured to selectively clamp the first bit line in response to the memory system operating in a particular mode, and where the second clamp and logic circuit is configured to selectively clamp the second bit line in response to the memory system operating in the particular mode; a sense amp connected to a pair of bit lines, the sense amp configured to generate a digital bit based on a difference between the bit lines of the pair of bit lines; and a latch connected to the sense amp, the latch configured to store data corresponding with the digital bit of the sense amp.

Implementations may include one or more of the following features. The memory system, where the particular mode is a read first mode. The memory system, where the first and second clamp and logic circuits do not respectively clamp the first and second bit lines in response to the memory system operating in a write first mode or in a no change mode. The memory system, where the first and second clamp and logic circuits clamp the first and second bit lines if, in addition to the memory system operating in the particular mode, a column of memory cells connected to the first and second bit lines of the first and second clamp and logic circuits is selected for a read or a write operation. The memory system, where the first clamp and logic circuit clamps the first bit line if, in addition to the memory system operating in the particular mode, the first bit line is used for a write operation. The memory system, where the second clamp and logic circuit clamps the second bit line if, in addition to the memory system operating in the particular mode, the second bit line is used for a write operation. The memory system, where the first and second clamp and logic circuits clamp the first and second bit lines if, in addition to the memory system operating in the particular mode, a column of memory cells connected to the first and second bit lines is being used for a read operation. The memory system, where the memory system includes a multiport memory.

One general aspect is a method of using a memory circuit, the method including operating the memory circuit in a particular mode; selecting a column of memory cells connected to a bit line of a clamp and logic circuit during a read or a write operation; and enabling the clamp and logic circuit based on whether the memory circuit is operating in the particular mode, the column of memory cells connected to the bit line of the clamp and logic circuit is selected during the read or write operation, the bit line connected to the clamp and logic circuit is not being used for a write operation, and the column of memory cells connected to the bit line of the clamp and logic circuit is being used for a read operation.

Implementations may include one or more of the following features. The method, where the clamp and logic circuit is enabled if the memory circuit is operating in a read first mode, the column of memory cells connected to the bit line of the clamp and logic circuit is selected during a read or a write operation, the bit line connected to the clamp and logic circuit is not being used for a write operation, and the column of memory cells connected to the bit line of the clamp and logic circuit is being used for a read operation. The method, where the clamp and logic circuit is disabled if any of the memory circuit is not operating in a read first mode, the column of memory cells connected to the bit line of the clamp and logic circuit is not selected during a read or a write operation, the bit line connected to the clamp and logic circuit is being used for a write operation, and the column of memory cells connected to the bit line of the clamp and logic circuit is not being used for a read operation. The method, where the particular mode is a read first mode.

While this invention has been described with reference to illustrative implementations, this description is not intended to be construed in a limiting sense. Various modifications and combinations of the illustrative implementations, as well as other implementations of the invention, will be apparent to persons skilled in the art upon reference to the description. It is therefore intended that the appended claims encompass any such modifications or implementations.

1. A memory circuit, comprising:
a plurality of bit lines;
a plurality of memory cells arranged in columns, each memory cell connected to a pair of bit lines; and
a plurality of clamp circuits, each comprising a first clamp and logic circuit connected to a first bit line and a second clamp and logic circuit connected to a second bit line,
wherein the first clamp and logic circuit is configured to selectively clamp the first bit line in response to the memory circuit operating in a particular mode, and
wherein the second clamp and logic circuit is configured to selectively clamp the second bit line in response to the memory circuit operating in the particular mode.

2. The memory circuit of claim 1, wherein the particular mode is a read first mode.

3. The memory circuit of claim 1, wherein the first and second clamp and logic circuits do not respectively clamp the first and second bit lines in response to the memory circuit operating in a write first mode or in a no change mode.

4. The memory circuit of claim 1, wherein the first and second clamp and logic circuits clamp the first and second bit lines if, in addition to the memory circuit operating in the particular mode, a column of memory cells connected to the first and second bit lines of the first and second clamp and logic circuits is selected for a read or a write operation.

5. The memory circuit of claim 1, wherein the first clamp and logic circuit clamps the first bit line if, in addition to the memory circuit operating in the particular mode, the first bit line is used for a write operation.

6. The memory circuit of claim 5, wherein the second clamp and logic circuit clamps the second bit line if, in addition to the memory circuit operating in the particular mode, the second bit line is used for a write operation.

7. The memory circuit of claim 1, wherein the first and second clamp and logic circuits clamp the first and second bit lines if, in addition to the memory circuit operating in the particular mode, a column of memory cells connected to the first and second bit lines is being used for a read operation.

8. The memory circuit of claim 1, wherein the memory circuit is a multiport memory.

9. A memory system, comprising:
a plurality of bit lines;
a plurality of memory cells arranged in columns, each memory cell connected to first and second bit lines;
a plurality of clamp circuits, each comprising a first clamp and logic circuit connected to a first bit line and a second clamp and logic circuit connected to a second bit line,
wherein the first clamp and logic circuit is configured to selectively clamp the first bit line in response to the memory system operating in a particular mode, and
wherein the second clamp and logic circuit is configured to selectively clamp the second bit line in response to the memory system operating in the particular mode;
a sense amp connected to a pair of bit lines, the sense amp configured to generate a digital bit based on a difference between the bit lines of the pair of bit lines; and
a latch connected to the sense amp, the latch configured to store data corresponding with the digital bit of the sense amp.

10. The memory system of claim 9, wherein the particular mode is a read first mode.

11. The memory system of claim 9, wherein the first and second clamp and logic circuits do not respectively clamp the first and second bit lines in response to the memory system operating in a write first mode or in a no change mode.

12. The memory system of claim 9, wherein the first and second clamp and logic circuits clamp the first and second bit lines if, in addition to the memory system operating in the particular mode, a column of memory cells connected to the first and second bit lines of the first and second clamp and logic circuits is selected for a read or a write operation.

13. The memory system of claim 9, wherein the first clamp and logic circuit clamps the first bit line if, in addition to the memory system operating in the particular mode, the first bit line is used for a write operation.

14. The memory system of claim 13, wherein the second clamp and logic circuit clamps the second bit line if, in addition to the memory system operating in the particular mode, the second bit line is used for a write operation.

15. The memory system of claim 9, wherein the first and second clamp and logic circuits clamp the first and second bit lines if, in addition to the memory system operating in the particular mode, a column of memory cells connected to the first and second bit lines is being used for a read operation.

16. The memory system of claim 9, wherein the memory system includes a multiport memory.

17. A method of using a memory circuit, the method comprising:
operating the memory circuit in a particular mode;
selecting a column of memory cells connected to a bit line of a clamp and logic circuit during a read or a write operation; and
enabling the clamp and logic circuit based on whether the memory circuit is operating in the particular mode, the column of memory cells connected to the bit line of the clamp and logic circuit is selected during the read or write operation, the bit line connected to the clamp and logic circuit is not being used for a write operation, and the column of memory cells connected to the bit line of the clamp and logic circuit is being used for a read operation.

18. The method of claim 17, wherein the clamp and logic circuit is enabled if the memory circuit is operating in a read first mode, the column of memory cells connected to the bit line of the clamp and logic circuit is selected during a read or a write operation, the bit line connected to the clamp and logic circuit is not being used for a write operation, and the column of memory cells connected to the bit line of the clamp and logic circuit is being used for a read operation.

19. The method of claim 17, wherein the clamp and logic circuit is disabled if any of: the memory circuit is not operating in a read first mode, the column of memory cells connected to the bit line of the clamp and logic circuit is not selected during a read or a write operation, the bit line connected to the clamp and logic circuit is being used for a write operation, and the column of memory cells connected to the bit line of the clamp and logic circuit is not being used for a read operation.

20. The method of claim 17, wherein the particular mode is a read first mode.
